(19) United States
(12) Patent Application Publication
(10) Pub. No.: US 2023/0389373 A1
(43) Pub. Date: Nov. 30, 2023

(54) LIGHT EMITTING DEVICE, IMAGE CAPTURING DEVICE, ELECTRONIC APPARATUS, AND MOVING BODY

(71) Applicant: CANON KABUSHIKI KAISHA, Tokyo (JP)

(72) Inventors: TAKESHI AKIYAMA, Kanagawa (JP); SATOSHI KATO, Kanagawa (JP); SHUSUKE YANAGAWA, Kanagawa (JP)

(21) Appl. No.: 18/316,509

(22) Filed: May 12, 2023

(30) Foreign Application Priority Data
May 27, 2022 (JP) 2022-087102

(51) Int. Cl. H10K 59/127; H10K 59/131

(52) U.S. Cl. CPC H10K 59/1275; H10K 59/131

(57) ABSTRACT

A light emitting device in which a light emitting element layer including a plurality of light emitting elements, a first substrate including at least a part of each of a plurality of unit circuits respectively connected to the plurality of light emitting elements, and a second substrate including at least a part of a control circuit configured to control the plurality of unit circuits are stacked. The device includes a first protective circuit arranged in the first substrate, and configured to protect the plurality of unit circuits, wherein a maximum voltage in the first substrate is higher than a maximum voltage in the second substrate.

### BACKGROUND OF THE INVENTION

### Field of the Invention

The present invention relates to a light emitting device, an image capturing device, an electronic apparatus, and a moving body.

### Description of the Related Art

A device in which a plurality of semiconductor substrates are stacked is known. Japanese Patent Laid-Open No. 2018-174246 describes a semiconductor device in which a first substrate and a second substrate are stacked. The first substrate includes a light emitting element, a light receiving element, and a first transistor for driving the light receiving element. The second substrate includes a second transistor for driving the light emitting element.

In a light emitting device having a structure in which a plurality of substrates are stacked, the distribution manner of a plurality of circuit elements or a plurality of circuit blocks, which form the light emitting device, can have influence on improvement of quality and reduction of manufacturing cost of the light emitting device.

### SUMMARY OF THE INVENTION

The present invention provides a technique advantageous in improving the quality and reducing the manufacturing cost of a light emitting device having a structure in which a plurality of substrates are stacked.

One of aspects of the present invention provides a light emitting device in which a light emitting element layer including a plurality of light emitting elements, a first substrate including at least a part of each of a plurality of unit circuits respectively connected to the plurality of light emitting elements, and a second substrate including at least a part of a control circuit configured to control the plurality of unit circuits are stacked, the device comprising a first protective circuit arranged in the first substrate, and configured to protect the plurality of unit circuits, wherein a maximum voltage in the first substrate is higher than a maximum voltage in the second substrate.

Further features of the present invention will become apparent from the following description of exemplary embodiments with reference to the attached drawings.

### BRIEF DESCRIPTION OF THE DRAWINGS

FIG. 1 is a view exemplarily showing the circuit arrangement of a display device according to the first embodiment;

FIG. 2 is a view exemplarily showing the arrangement of a pixel;

FIGS. 3A to 3G are views each exemplarily showing the circuit arrangement of a protective circuit;

FIGS. 4A and 4B are views showing two examples of the sectional structure of a pixel array portion;

FIGS. 5A to 5C are views exemplarily and schematically showing the sectional structure of the display device or light emitting device according to the first embodiment;

FIGS. 6A to 6C are views exemplarily and schematically showing the sectional structure of a display device or light emitting device according to the second embodiment;

FIGS. 7A to 7C are views exemplarily and schematically showing the sectional structure of a display device or light emitting device according to the third embodiment;

FIGS. 8A to 8C are views exemplarily and schematically showing the sectional structure of a display device or light emitting device according to the fourth embodiment;

FIG. 9 is a view showing an application example of the display device represented by the first to fourth embodiments;

FIGS. 10A and 10B are views each showing an application example of the display device represented by the first to fourth embodiments;

FIGS. 11A and 11B are views each showing an application example of the display device represented by the first to fourth embodiments;

FIGS. 12A and 12B are views each showing an application example of the display device represented by the first to fourth embodiments; and

FIGS. 13A and 13B are views each showing an application example of the display device represented by the first to fourth embodiments;

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

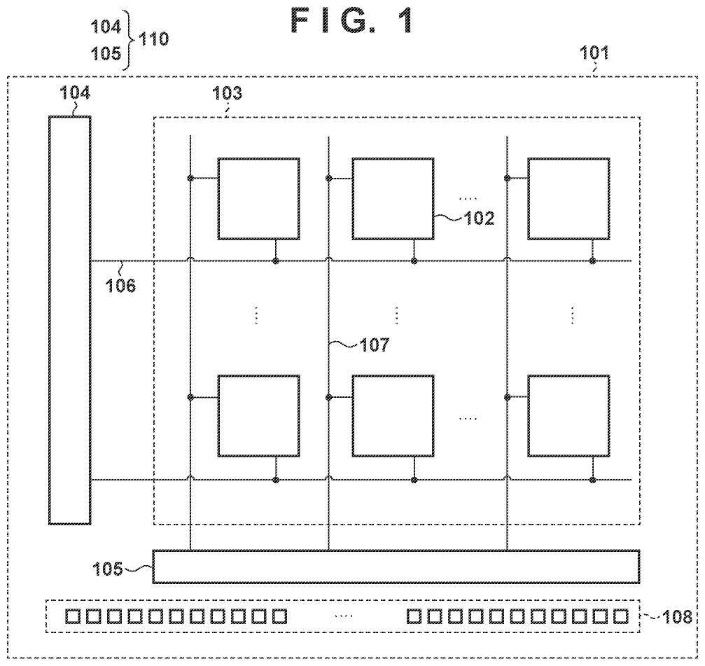

First, an example in which the light emitting device according to the present invention is embodied as a display device will be described below. A display device 101 described below may be read as a light emitting device. FIG. 1 exemplarily shows the circuit arrangement of the display device 101 according to the first embodiment. The display device 101 includes a pixel array portion 103, a vertical scanning circuit 104, a signal output circuit 105, and an input/output unit 108. The pixel array portion 103 is a block in which a plurality of pixels 102 are arranged so as to form a plurality of rows and a plurality of columns. The vertical scanning circuit 104 outputs a control signal to a plurality of scanning lines 106 so as to control the plurality of pixels 102 on a row basis. The signal output circuit 105 causes the pixels 102 in the row selected by the vertical scanning circuit 104 to output signals via a plurality of column signal lines 107. The vertical scanning circuit 104 and the signal output circuit 105 can form a control circuit 110 configured to control the circuit of the pixel array portion 103. The input/output unit 108 can include pad electrodes, which are used to input supply voltages to the pixel array portion 103, the vertical scanning circuit 104, and the signal output circuit 105, and to input/output signals to/from them, and protective circuits electrically connected to the pad electrodes. Note that the shape of the pad electrode is arbitrary. For example, the pad electrode can have a square shape, or a rectangular shape other than a square shape. The protective circuit to be described later can be electrically connected to the pad electrode.

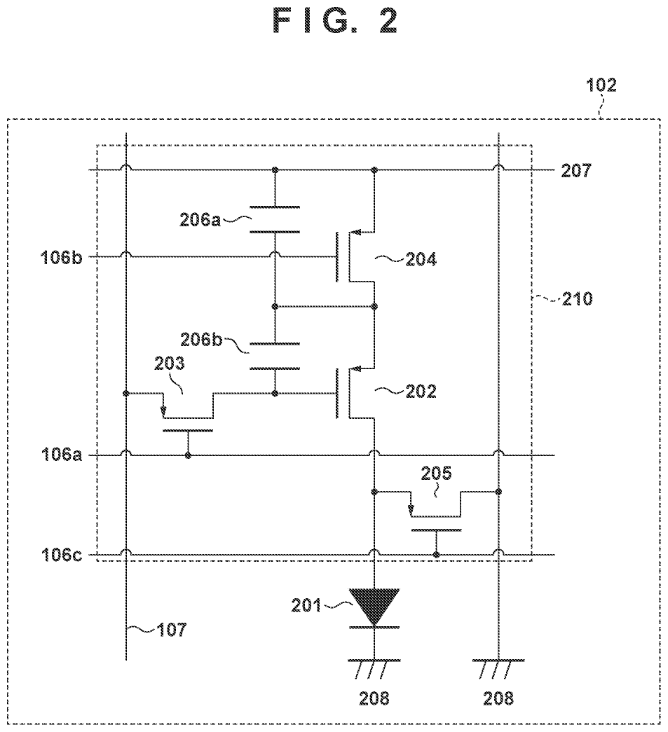

FIG. 2 exemplarily shows the arrangement of the pixel 102. The pixel 102 can include, for example, a light emitting element 201, a drive transistor 202, a write transistor 203, a light emission control transistor 204, a reset transistor 205, and capacitive elements 206a and 206b. The light emitting element 201 can be, for example, an organic light emitting element. The light emitting element 201 can include, for example, an organic layer including a light emitting element layer arranged between an anode electrode and a cathode electrode. The organic layer can include, in addition to the light emitting element layer, at least one of a hole injection layer, a hole transport layer, an electron injection layer, and an electron transport layer. Among a plurality of elements forming the pixel 102, elements other than the light emitting element 201 can be understood as components of a pixel circuit 210. When the display device 101 is understood as a light emitting device, a term “pixel” may be understood to refer to a light emitting unit, and the pixel circuit 210 may be understood as a unit circuit connected to the light emitting unit or the light emitting element 201. The vertical scanning circuit 104 and signal output circuit 105 described above can form the control circuit 110 configured to control a plurality of the pixel circuits 210 or a plurality of the unit circuits.

Hereinafter, as an example, a case will be described in which the drive transistor 202 is connected to the anode electrode of the light emitting element 201, and all the transistors related to driving of the light emitting element 201 are p-type transistors. However, another arrangement may also be employed. For example, the polarity and conductivity type may all be reversed from those in the example described here. In accordance with the polarity and conductivity type, the supplied potential and connection to each transistor can be changed. The total number of transistors and capacitive elements and the combination of the conductivity types of the transistors are merely examples, and the present invention is not limited to this arrangement.

One of the source and drain of the drive transistor 202 can be electrically connected to the anode electrode of the light emitting element 201, and electrically connected to one of the source and drain of the reset transistor 205. The cathode electrode of the light emitting element 201 can be connected to a first power supply potential 208 (to be referred to as a Vss hereinafter). The other of the source and drain of the drive transistor 202 can be electrically connected to one of the source and drain of the light emission control transistor 204, and also electrically connected to one electrode of each of the capacitive elements 206a and the capacitive element 206b. The other electrode of the capacitive element 206a can be electrically connected to a second power supply potential 207 (to be referred to as a Vdd hereinafter). The other of the source and drain of the light emission control transistor 204 can be electrically connected to the Vdd 207. The gate of the light emission control transistor 204 can be electrically connected to a scanning line 106b. One of the source and drain of the write transistor 203 can be electrically connected to the gate of the drive transistor 202 and the other electrode of the capacitive element 206b. The other of the source and drain of the write transistor 203 can be electrically connected to the column signal line 107. The gate of the write transistor 203 can be electrically connected to a scanning line 106a. The other of the source and drain of the reset transistor 205 can be electrically connected to the Vss 208. The gate of the reset transistor 205 can be electrically connected to a scanning line 106c.

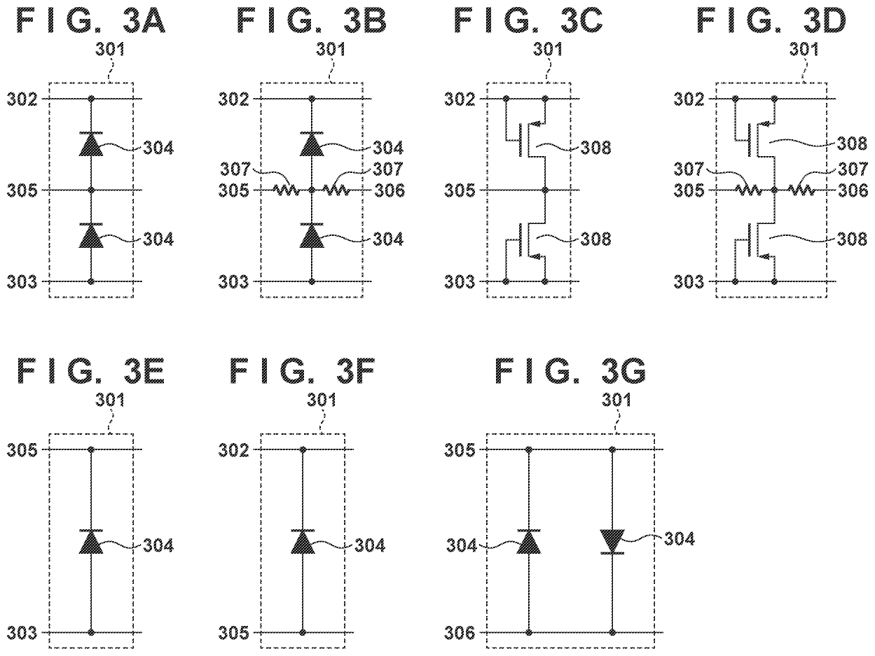

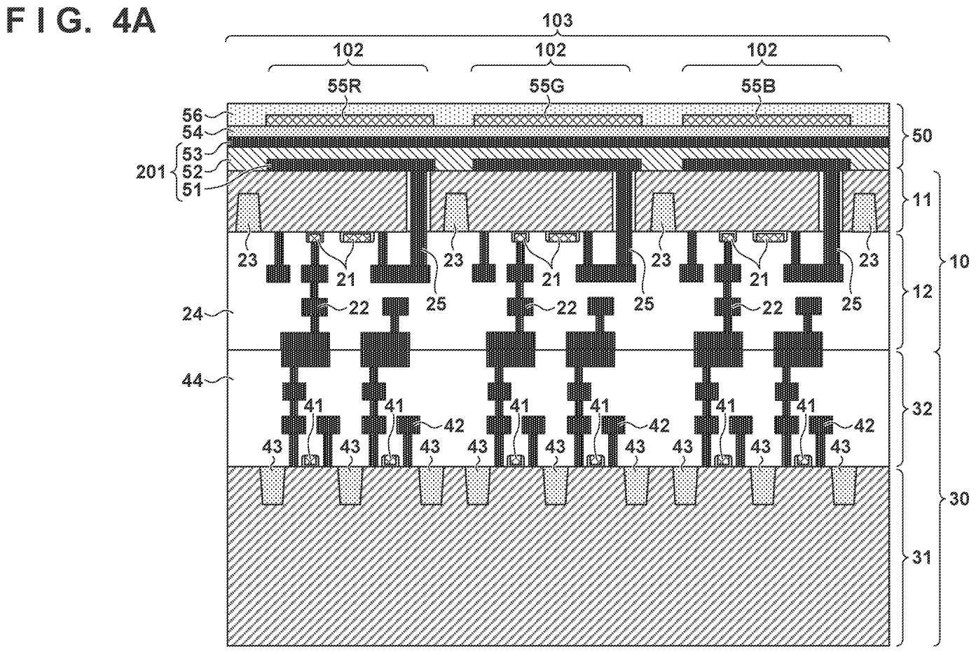

Next, some examples of the circuit arrangement of the protective circuit will be described. Each of FIGS. 3A to 3G shows the arrangement example of a protective circuit 301 in the input/output unit 108. The circuit arrangement of the protective circuit 301 can be selected in accordance with the kind of a signal or potential (for example, a power supply potential, an analog input/output signal, or a digital input/output signal) to be given to the pad electrode electrically connected to the protective circuit 301. Each of FIGS. 3A to 3G shows some of a power supply line 302, a ground line 303, diodes 304, resistor elements 307, gate-grounded transistors 308, and signal lines 305 and 306. Corresponding pad electrodes can be electrically connected to the power supply line 302, the ground line 303, and the signal lines 305 and 306, respectively. A term “input/output” can be used as a term that means both “input” and “output”, or a term including a term meaning “input” and a term meaning “output”.

In the example shown in FIG. 3G, the same potential is given to the signal lines 305 and 306, and the diode 304 whose forward direction is from the signal line 305 to the signal line 306, and the diode 304 whose forward direction is from the signal line 306 to the signal line 305 are provided. In the examples shown in FIGS. 3A, 3B, 3C, and 3D, when a surge voltage is input to the signal lines 305 and 306, the diodes 304 or the gate-grounded transistors 308 can form a transmission path of the surge voltage to the power supply line 302 or the ground line 303. With this, the surge voltage can be hardly transmitted to the element electrically connected to the pad electrode. Note that the protective circuit 301 may have an arrangement other than the arrangements shown in FIGS. 3A to 3G. As the protective circuit 301, a buffer having a hysteresis function may be employed. Alternatively, as the protective circuit 301, a pull-up resistor or a pull-down resistor may be provided between the signal lines 305 and 306 and the power supply line or the ground line.

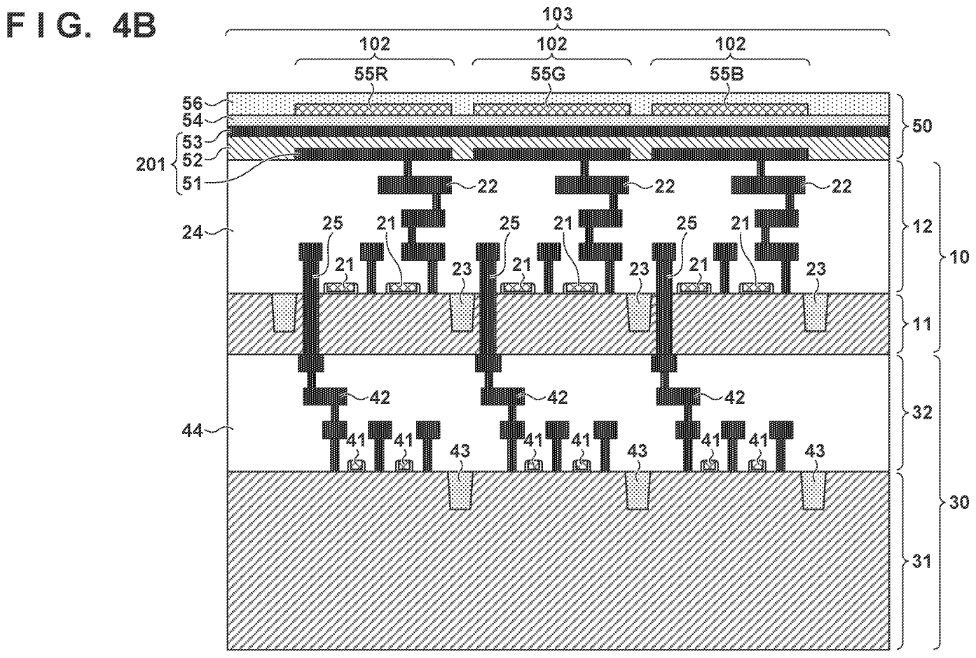

FIG. 4A schematically shows an example of the sectional structure of the pixel array portion 103. The display device 101 can have the arrangement in which a light emitting element layer 50, a first substrate 10, and a second substrate 30 are stacked. The light emitting element layer 50 can include a plurality of the light emitting elements 201. The first substrate 10 can include at least a part of each of the plurality of pixel circuits (unit circuits) 210 respectively connected to the plurality of the light emitting elements 201. The second substrate 30 can include at least a part of the control circuit 110 configured to control the plurality of the pixel circuits 210. Here, as has been described above, the control circuit 110 can include, for example, the vertical scanning circuit 104 and the signal output circuit 105. The first substrate 10 can include a first semiconductor substrate 11 and a first wiring layer 12 stacked on the first semiconductor substrate 11. The second substrate 30 can include a second semiconductor substrate 31 and a second wiring layer 32 stacked on the second semiconductor substrate 31. The maximum voltage in the first substrate 10 is higher than the maximum voltage in the second substrate 30.

In the example shown in FIG. 4A, the first substrate 10 and the second substrate 30 are bonded such that the first wiring layer 12 of the first substrate 10 and the second wiring layer 32 of the second substrate 30 are bonded. In another point of view, the first semiconductor substrate 11 is arranged between the light emitting element layer 50 and the first wiring layer 12, and the second wiring layer 32 is arranged between the first substrate 10 and the second semiconductor substrate 31. The first wiring layer 12 can include an electrically conductive path 22 arranged so as to form one or a plurality of layers, and an interlayer insulating film 24 supporting and surrounding the electrically conductive path 22. The electrically conductive path 22 can include a metal pattern or a metallized pattern. The electrically conductive path 22 can also include a contact plug and/or a via plug. The first semiconductor substrate 11 can include a penetrating electrode 25 for electrically connecting the electrically conductive path 22 in the first wiring layer 12 and the light emitting element 201 in the light emitting element layer 50. The semiconductor substrate 11 can be backgrinded to facilitate formation of the penetrating electrode 25. The second wiring layer 32 can include an electrically conductive path 42 arranged so as to form one or a plurality of layers, and an interlayer insulating film 44 supporting and surrounding the electrically conductive path 42. The electrically conductive path 42 can include a metal pattern or a metallized pattern. The electrically conductive path 42 can also include a contact plug and/or a via plug.

Each of the interlayer insulating films 24 and 44 can include, for example, at least one of a silicon oxide film and a silicon nitride film. When the electrically conductive path 22 forms a plurality of layers, all of the plurality of layers may be made of the same material, or materials corresponding to the respective layers may be employed. Similarly, when the electrically conductive path 42 forms a plurality of layers, all of the plurality of layers may be made of the same material, or materials corresponding to the respective layers may be employed.

A plurality of first transistors 21 (corresponding to the transistors 202, 203, and 204 described above) forming the pixel circuit (unit circuit) 210 configured to drive the light emitting element 201 can be provided in the interface between the first semiconductor substrate 11 and the first wiring layer 12 and its vicinity. Shallow Trench Isolations (STIs) 23 serving as isolation portions for electrically separating the plurality of transistors 21 from each other can be provided in the first semiconductor substrate 11. A plurality of second transistors 41 forming the control circuit 110 configured to control the pixel circuit 210 of each of the plurality of pixels in the pixel array portion 103 can be provided in the interface between the second semiconductor substrate 31 and the second wiring layer 32 and its vicinity. Shallow Trench Isolations (STIs) 43 serving as isolation portions for electrically separating the plurality of transistors 41 from each other can be provided in the second semiconductor substrate 31.

The light emitting element layer 50 can be arranged on the first semiconductor substrate 11 of the first substrate 10. The light emitting element layer 50 can include the light emitting element 201 of each of the plurality of pixels 102 in the pixel array portion 103. Each light emitting element 201 can include a lower electrode 51, an organic layer 52, and an upper electrode 53. In an example, the upper electrode 53 can be provided commonly for the plurality of the light emitting elements 201. In an example, the lower electrode 51 is an anode electrode, and the upper electrode 53 is a cathode electrode. However, in another example, the lower electrode 51 is a cathode electrode, and the upper electrode 53 is an anode electrode. The organic layer 52 can include at least a light emitting element layer. The organic layer 52 may further include, in addition to the light emitting element layer, at least one of a hole injection layer, a hole transport layer, an electron injection layer, and an electron transport layer. In an example, the lower electrode 51 is formed for each pixel 102 and separated from another lower electrode 51. The lower electrode 51 of each pixel 102 can be electrically connected to the corresponding electrically conductive path 22. In each pixel 102, light emission of the light emitting element 201 can be controlled based on a driving signal transmitted from the pixel circuit 210 arranged in the first substrate 10. The light emitting element layer 50 can include a sealing layer 54 covering the plurality of the light emitting elements 201. The light emitting element layer 50 may further include a plurality of color filters 55 arranged on the sealing layer 54, and a protective layer 56 covering the plurality of color filters 55.

FIG. 4B schematically shows another example of the sectional structure of the pixel array portion 103. Here, only differences from FIG. 4A will be described. In the example shown in FIG. 4B, the first substrate 10 and the second substrate 30 are bonded such that the first semiconductor substrate 11 of the first substrate 10 and the second wiring layer 32 of the second substrate 30 are bonded. In another point of view, the first wiring layer 12 is arranged between the light emitting element layer 50 and the first semiconductor substrate 11, and the second wiring layer 32 is arranged between the first substrate 10 and the second semiconductor substrate 31. The first semiconductor substrate 11 can include the penetrating electrode 25 for electrically connecting the electrically conductive path 22 in the first wiring layer 12 of the first substrate 10 and the electrically conductive path 42 in the second wiring layer 32 of the second substrate 30. The lower electrode 51 of the light emitting element 201 of each pixel can be electrically connected to the electrically conductive path 22 of the corresponding pixel circuit.

Hereinafter, an example will be described in which a protective circuit is provided in the arrangement shown in FIG. 4A, but the protective circuit may be provided in the arrangement shown in FIG. 4B.

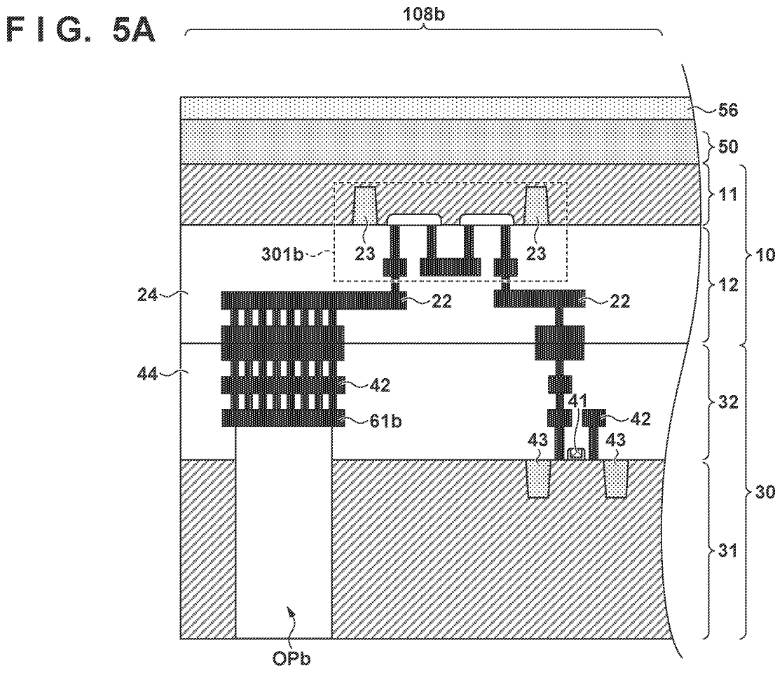

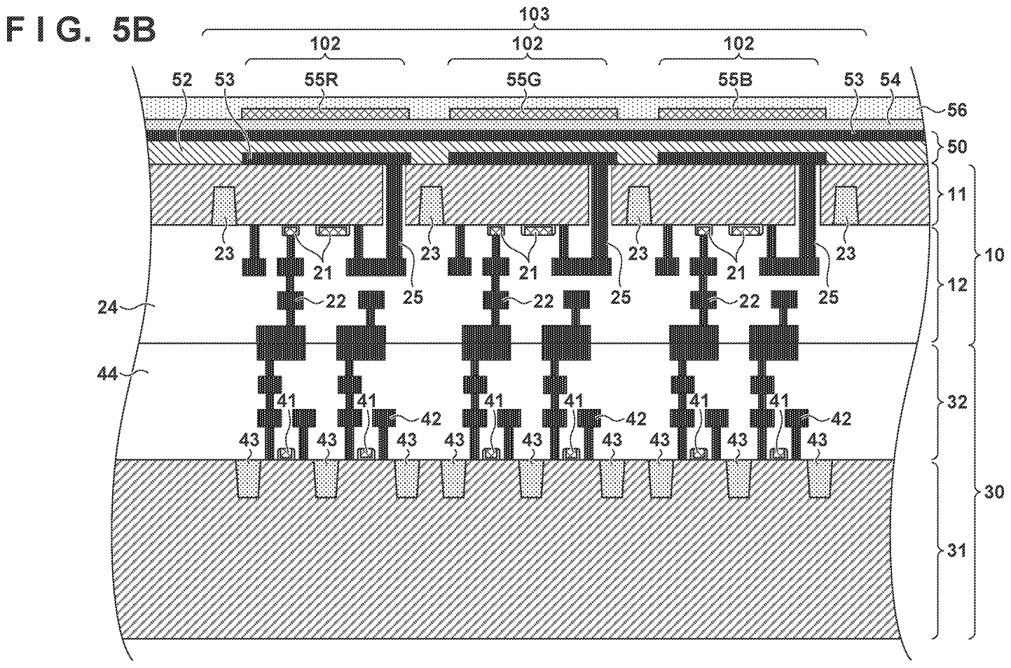

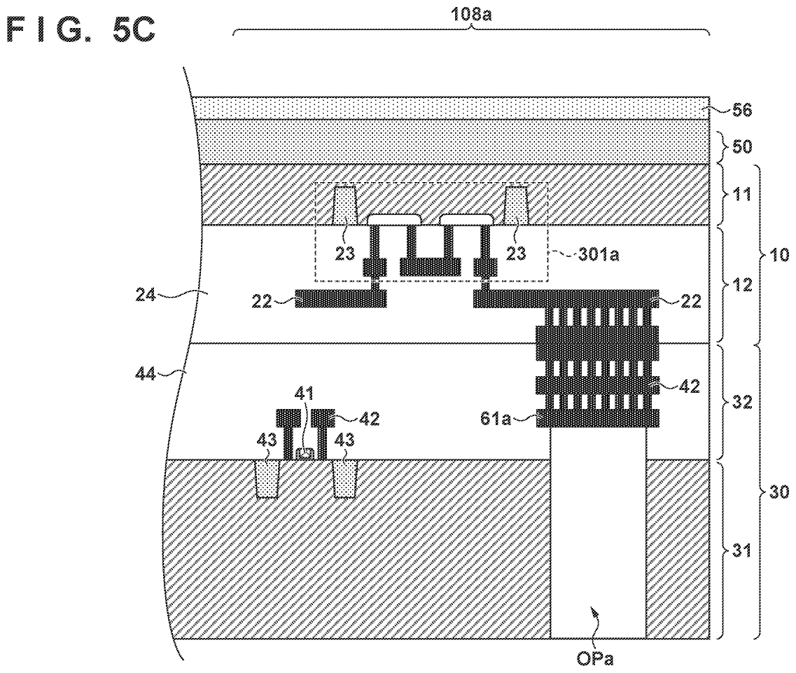

FIGS. 5A to 5C exemplarily and schematically show the sectional structure of the display device 101 according to the first embodiment. The pixel array portion 103 can have an arrangement similar to the arrangement shown in FIG. 4A. The display device 101 can include a first input/output unit 108a. The first input/output unit 108a can include a first protective circuit 301a electrically connected to the transistor 21 forming the pixel circuit 210 arranged in the first substrate 10, and a first pad electrode 61a electrically connected to the first protective circuit 301a. A potential or signal to be supplied to the circuit element such as the transistor 21 arranged in the first substrate 10 can be given to the first pad electrode 61a.

The maximum voltage (first voltage) in the first substrate 10 is higher than the maximum voltage (second voltage) in the second substrate 30. For example, a high voltage close to 10 V can be supplied to the first substrate 10. Accordingly, the circuit element such as the transistor 21 arranged in the first substrate 10 has an arrangement that can withstand a high voltage. Therefore, the first protective circuit 301a can also be configured to have an arrangement that can withstand a high voltage. In terms of manufacture, the first substrate 10 can be manufactured by a high withstand voltage process, and the second substrate 30 can be manufactured by a fine process.

The first protective circuit 301a can be arranged in the first substrate 10, and one of the input/output terminals of the first protective circuit 301a can be electrically connected to one of the source and drain of the transistor 21 via the electrically conductive path 22. The first pad electrode 61a can be arranged in the second wiring layer 32 of the second substrate 30, and can be electrically connected to the other of the input/output terminals of the first protective circuit 301a via the electrically conductive paths 42 and 22. The first pad electrode 61a can be formed together with the electrically conductive path 42 in a step of forming the electrically conductive path 42. The second substrate 30 can be provided with a first opening portion OPa for exposing the first pad electrode 61a. Here, more specifically, the first opening portion OPa can be provided so as to expose the first pad electrode 61a to the space on the side of, of two surfaces of the display device 101, the surface (back surface) different from the surface provided with the light emitting element layer 50.

The display device 101 can include a second input/output unit 108b. The second input/output unit 108b can include a second protective circuit 301b electrically connected to the transistor 41 forming the control circuit 110 arranged in the second substrate 30, and a second pad electrode 61b electrically connected to the second protective circuit 301b. A potential or signal to be supplied to the circuit element such as the transistor 41 arranged in the second substrate 30 can be given to the second pad electrode 61b. A low voltage lower than the voltage to be supplied to the circuit element such as the transistor 21 arranged in the first substrate 10 can be supplied to the circuit element such as the transistor 41 arranged in the second substrate 30. For example, a low voltage of about 1 V to 4 V can be supplied to the circuit element such as the transistor 41 arranged in the second substrate 30.

When the pixel circuit 210 includes the element (for example, the transistor or the capacitive element) to which a high voltage is not applied, the element may be arranged in the second substrate 30. The second protective circuit 301b electrically connected to the element such as the transistor 41 in the second substrate 30 may be arranged in the first substrate 10 and formed together with the element in the first substrate 10, but may be arranged in the second substrate 30 and formed together with the element of the second substrate 30.

In an example, the second protective circuit 301b can be arranged in the first substrate 10, and one of the input/output terminals of the second protective circuit 301b can be electrically connected to one of the source and drain of the transistor 41 via the electrically conductive paths 22 and 42. The second pad electrode 61b can be arranged in the second wiring layer 32 of the second substrate 30, and electrically connected to the other of the input/output terminals of the second protective circuit 301b via the electrically conductive paths 42 and 22. The second pad electrode 61b can be formed together with the electrically conductive path 42 in a step of forming the electrically conductive path 42. The second substrate 30 can be provided with a second opening portion OPb for exposing the second pad electrode 61b. Here, more specifically, the second opening portion OPb can be provided so as to expose the second pad electrode 61b to the space on the side of, of two surfaces of the display device 101, the surface (back surface) different from the surface provided with the light emitting element layer 50.

In order to arrange the first protective circuit 301a in the second substrate that can be manufactured by the fine process, a high withstand voltage process for forming the element that can withstand a high voltage of, for example, close to V is necessarily added to the fine process for manufacturing the second substrate 30. Thus, it is necessary to develop a fine process that copes with the high withstand voltage process, and this can lead to an increase in cost. In the first embodiment, the first protective circuit 301a in the first input/output unit 108a and the second protective circuit 301b in the second input/output unit 108b are arranged in the first substrate 10 that can be manufactured by the high withstand voltage process. Hence, it is possible to obtain the Electrostatic Discharge resistance (to be referred to as the ESD withstand voltage hereinafter) that can withstand a high voltage by using the current high withstand voltage process and fine process intact without developing a new process. When the second protective circuit 301b connected to the transistor 41 that can operate with a relatively low voltage is arranged in the first substrate 10, a high ESD resistance can be obtained as compared to a case in which the second protective circuit 301b is arranged in the second substrate 30.

The above-described effect can also be obtained in the structure in which the second substrate 30 is arranged between the light emitting element layer 50 and the first substrate 10. Accordingly, the second substrate 30 may be arranged between the light emitting element layer 50 and the first substrate 10.

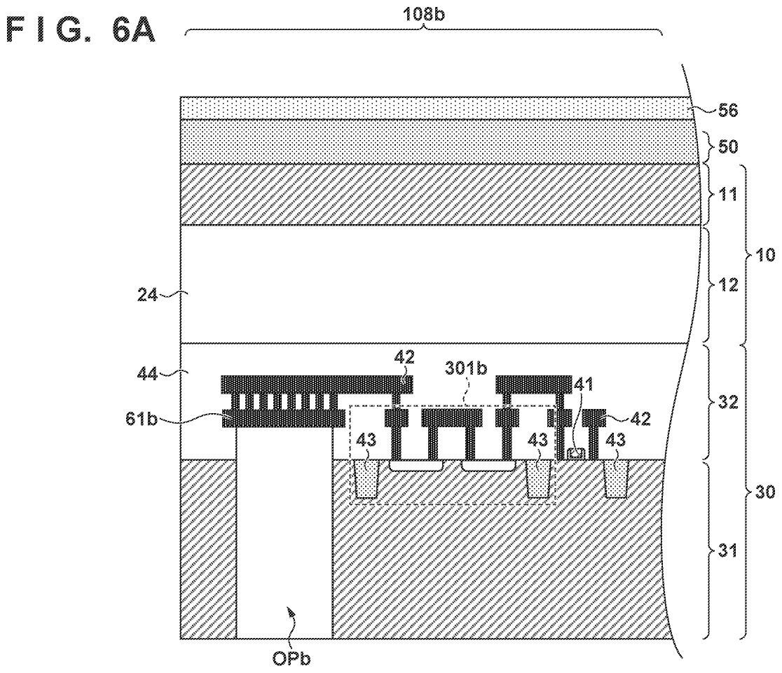

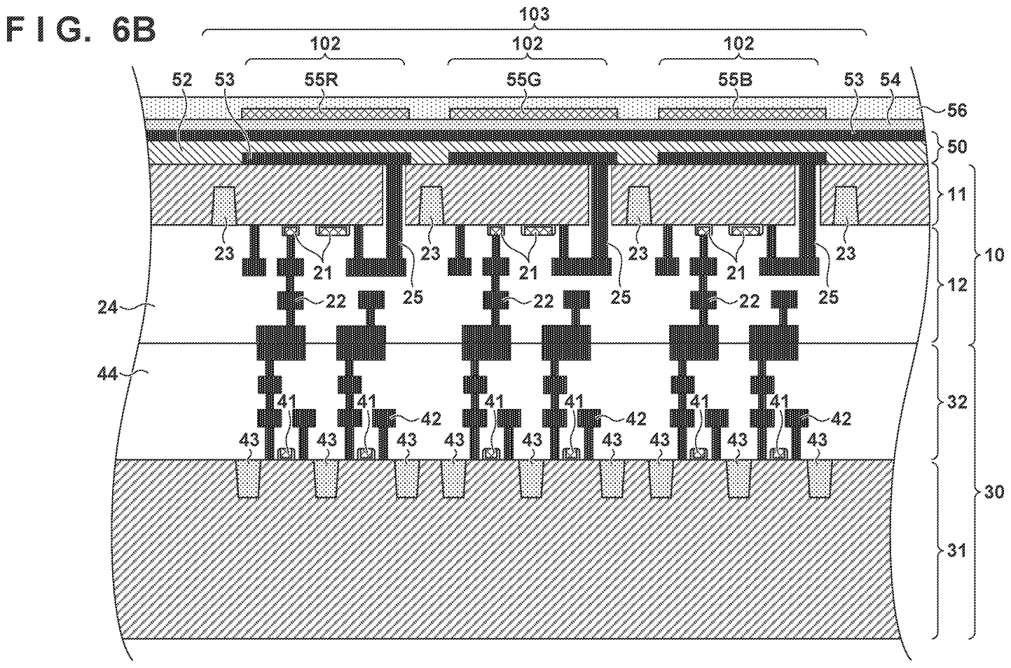

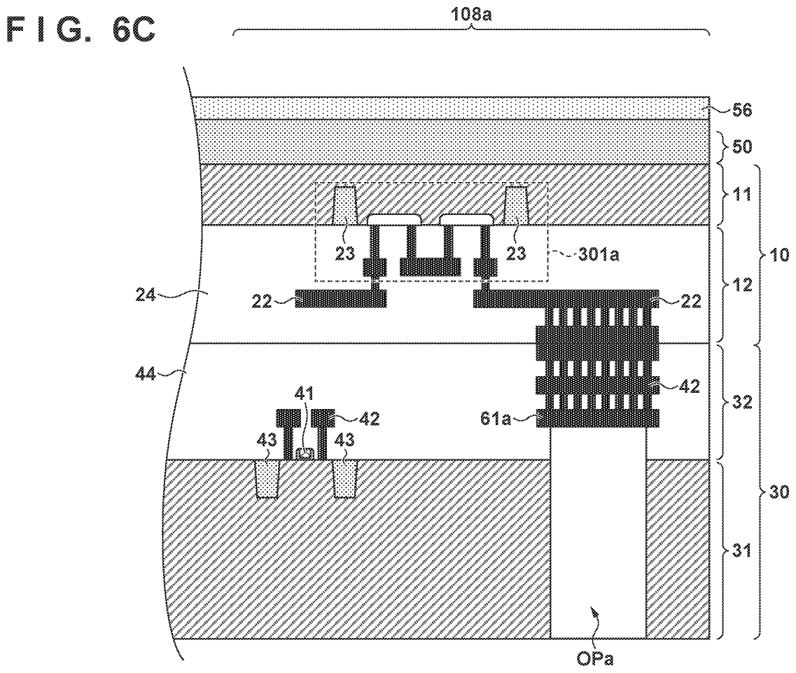

With reference to FIGS. 6A to 6C, a display device 101 according to the second embodiment will be described below. Matters not mentioned as the second embodiment can follow the first embodiment. In the second embodiment, a second protective circuit 301b in a second input/output unit 108b can be arranged in a second substrate 30 that can be manufactured by a fine process, and formed by the fine process together with the element such as the transistor 41. Forming the transistor 41 by the fine process is advantageous in increasing the operation speed, reducing noise, increasing the image quality, and the like.

The second input/output unit 108b can include the second protective circuit 301b electrically connected to the transistor 41 forming a control circuit 110 arranged in the second substrate 30, and a second pad electrode 61b electrically connected to the second protective circuit 301b. A potential or signal to be supplied to the circuit element such as the transistor 41 arranged in the second substrate 30 can be given to the second pad electrode 61b. A low voltage lower than the voltage to be supplied to the circuit element such as the transistor 21 arranged in a first substrate 10 can be supplied to the circuit element such as the transistor 41 arranged in the second substrate 30. For example, a low voltage of about 1 V to 4 V can be supplied to the circuit element such as the transistor 41 arranged in the second substrate 30.

One of the input/output terminals of the second protective circuit 301b can be electrically connected to one of the source and drain of the transistor 41 via an electrically conductive path 42. The second pad electrode 61b can be arranged in a second wiring layer 32 of the second substrate 30, and can be electrically connected to the other of the input/output terminals of the second protective circuit 301b via the electrically conductive path 42. The second pad electrode 61b can be formed together with the electrically conductive path 42 in a step of forming the electrically conductive path 42. The second substrate 30 can be provided with a second opening portion OPb for exposing the second pad electrode 61b. Here, more specifically, the second opening portion OPb can be provided so as to expose the second pad electrode 61b to the space on the side of, of two surfaces of the display device 101, the surface (back surface) different from the surface provided with a light emitting element layer 50.

In order to arrange a first protective circuit 301a in the second substrate that can be manufactured by a fine process, a high withstand voltage process for forming the element that can withstand a high voltage of, for example, close to V is necessarily added to the fine process for manufacturing the second substrate 30. Thus, it is necessary to develop the fine process that copes with the high withstand voltage process, and this can lead to an increase in cost. In the second embodiment, the first protective circuit 301a in a first input/output unit 108a is arranged in a first substrate 10 that can be manufactured by the high withstand voltage process, and the second protective circuit 301b in the second input/output unit 108b is arranged in the second substrate 30 that can be manufactured by the fine process. Hence, it is possible to obtain the ESD withstand voltage that can withstand a high voltage by using the current high withstand voltage process and fine process intact without developing a new process. Arranging the second protective circuit 301b in the second substrate 30 is advantageous in increasing the operation speed of the display device 101, reducing noise, and increasing the image quality, and the like.

The above-described effect can also be obtained in the structure in which the second substrate 30 is arranged between the light emitting element layer 50 and the first substrate 10. Accordingly, the second substrate 30 may be arranged between the light emitting element layer 50 and the first substrate 10.

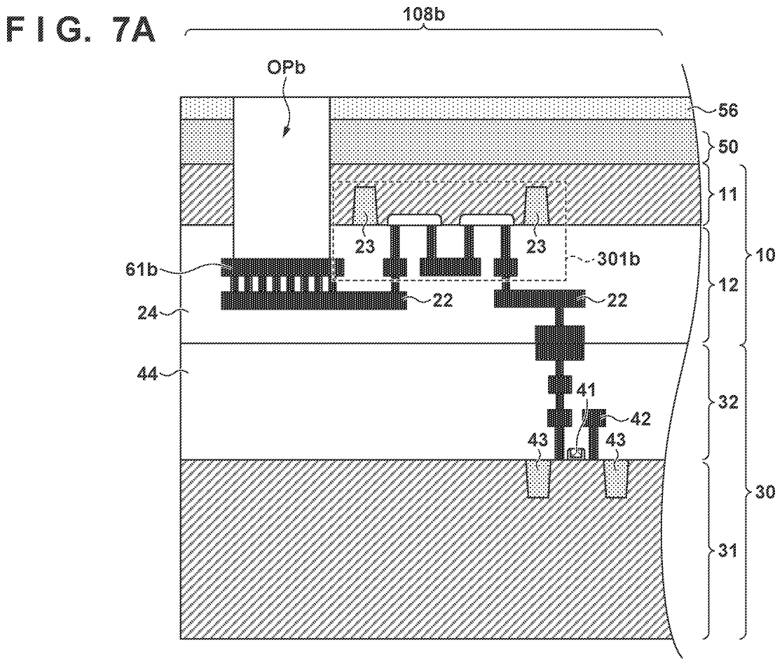

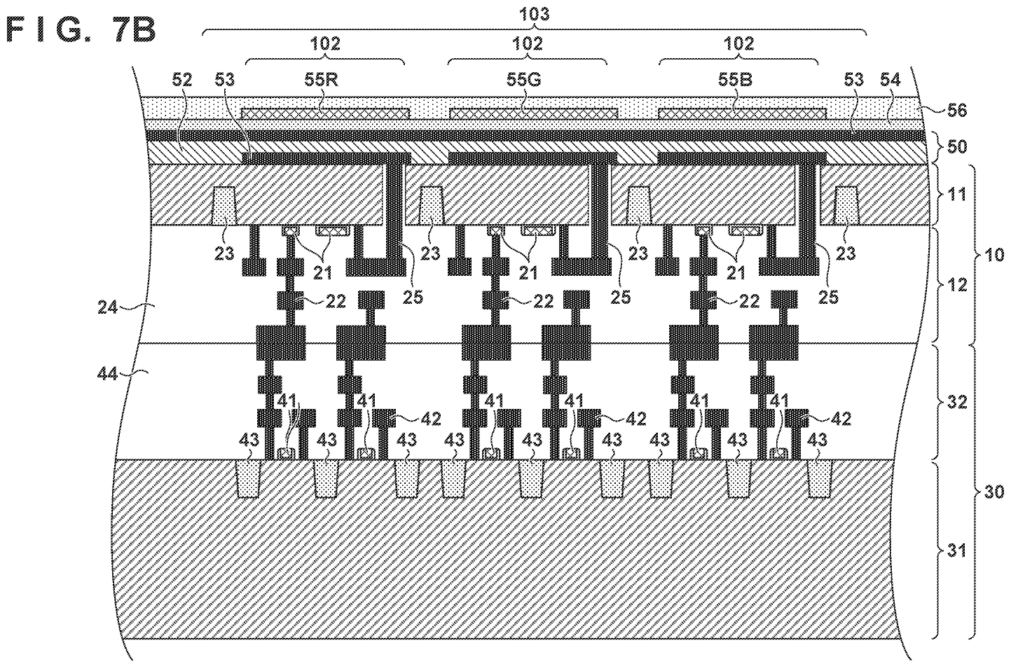

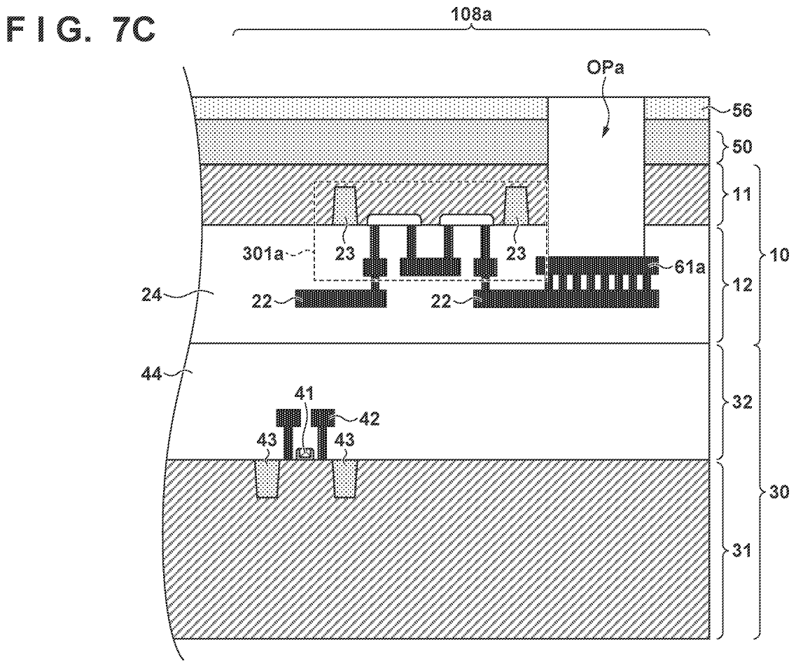

With reference to FIGS. 7A to 7C, a display device 101 according to the third embodiment will be described below. Matters not mentioned as the third embodiment can follow the first embodiment. In the third embodiment, a first opening portion OPa that exposes a first pad electrode 61a is provided so as to expose the first pad electrode 61a to the space on the side of, of two surfaces of the display device 101, the surface provided with a light emitting element layer 50. Further, in the third embodiment, a second opening portion OPb that exposes a second pad electrode 61b is provided so as to expose the second pad electrode 61b to the space on the side of, of two surfaces of the display device 101, the surface provided with the light emitting element layer 50.

The first pad electrode 61a can be arranged in a first wiring layer 12 of a first substrate 10, and electrically connected to one of the input/output terminals of a first protective circuit 301a via an electrically conductive path 22. The first pad electrode 61a can be formed together with the electrically conductive path 22 in a step of forming the electrically conductive path 22. The second electrode pad 61b can be arranged in the first wiring layer 12 of the first substrate 10, and electrically connected to one of the input/output terminals of a second protective circuit 301b via the electrically conductive path 22. The second pad electrode 61b can be formed together with the electrically conductive path 22 in the step of forming the electrically conductive path 22.

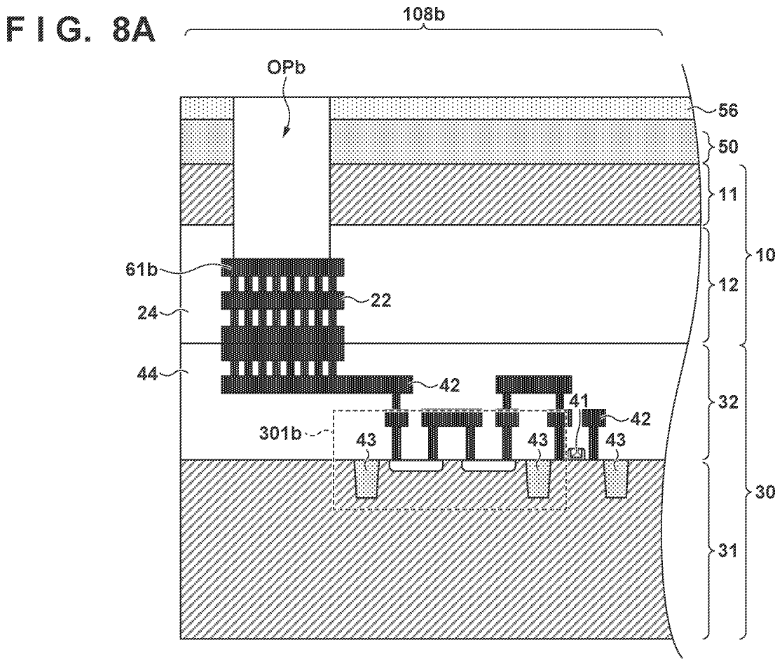

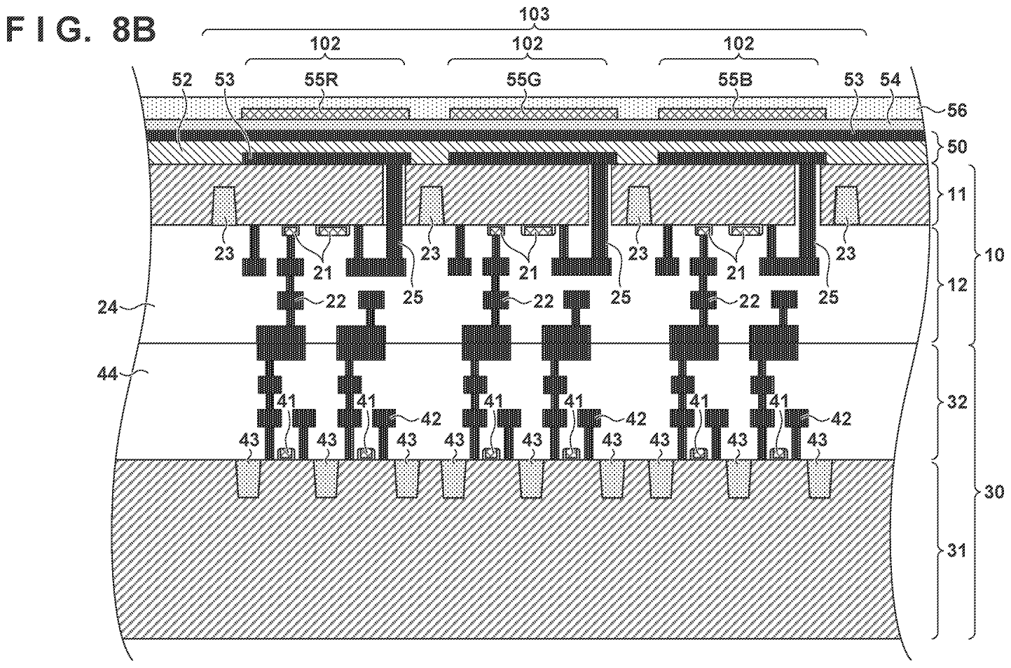

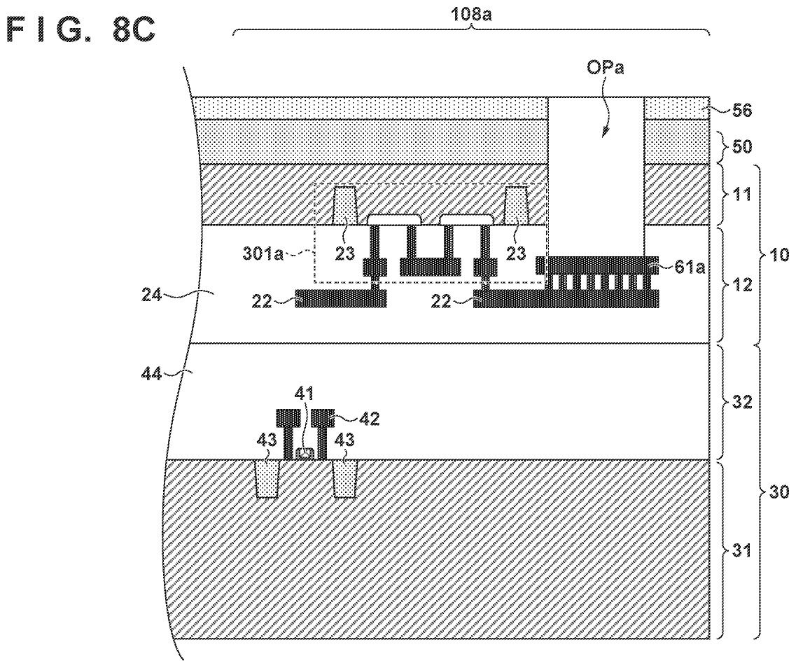

With reference to FIGS. 8A to 8C, a display device 101 according to the fourth embodiment will be described below. Matters not mentioned as the fourth embodiment can follow the second embodiment. In the fourth embodiment, a first opening portion OPa that exposes a first pad electrode 61a is provided so as to expose the first pad electrode 61a to the space on the side of, of two surfaces of the display device 101, the surface provided with a light emitting element layer 50. Further, in the fourth embodiment, a second opening portion OPb that exposes a second pad electrode 61b is provided so as to expose the second pad electrode 61b to the space on the side of, of two surfaces of the display device 101, the surface provided with the light emitting element layer 50.

The first pad electrode 61a can be arranged in a first wiring layer 12 of a first substrate 10, and electrically connected to one of the input/output terminals of a first protective circuit 301a via an electrically conductive path 22. The first pad electrode 61a can be formed together with the electrically conductive path 22 in a step of forming the electrically conductive path 22. The second electrode pad 61b can be arranged in the first wiring layer 12 of the first substrate 10, and electrically connected to one of the input/output terminals of a second protective circuit 301b via the electrically conductive path 22 and an electrically conductive path 42. The second pad electrode 61b can be formed together with the electrically conductive path 22 in the step of forming the electrically conductive path 22.

Next, application examples of the display device according to the embodiment will be described with reference to drawings. FIG. 9 is a schematic view showing a display device 1000 as one example of application examples of a light emitting device DD according to the embodiment. The display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Transistors are printed on the circuit board 1007. The battery 1008 is unnecessary if the display device is not a portable apparatus. Even when the display device is a portable apparatus, the battery 1008 may be provided at another position.

The display device according to the embodiment can include color filters of red, green, and blue. The color filters of red, green, and blue can be arranged in a delta array.

The display device according to the embodiment can also be used for a display unit of a portable terminal. At this time, the display unit can have both a display function and an operation function. Examples of the portable terminal are a portable phone such as a smartphone, a tablet, and a head mounted display.

The display device according to the embodiment can be used for a display unit of an image capturing device including an optical unit including a plurality of lenses, and an image sensor for receiving light having passed through the optical unit. The image capturing device can include a display unit for displaying information acquired by the image sensor. In addition, the display unit can be either a display unit exposed outside the image capturing device, or a display unit arranged in the finder. The image capturing device can be a digital camera or a digital video camera.

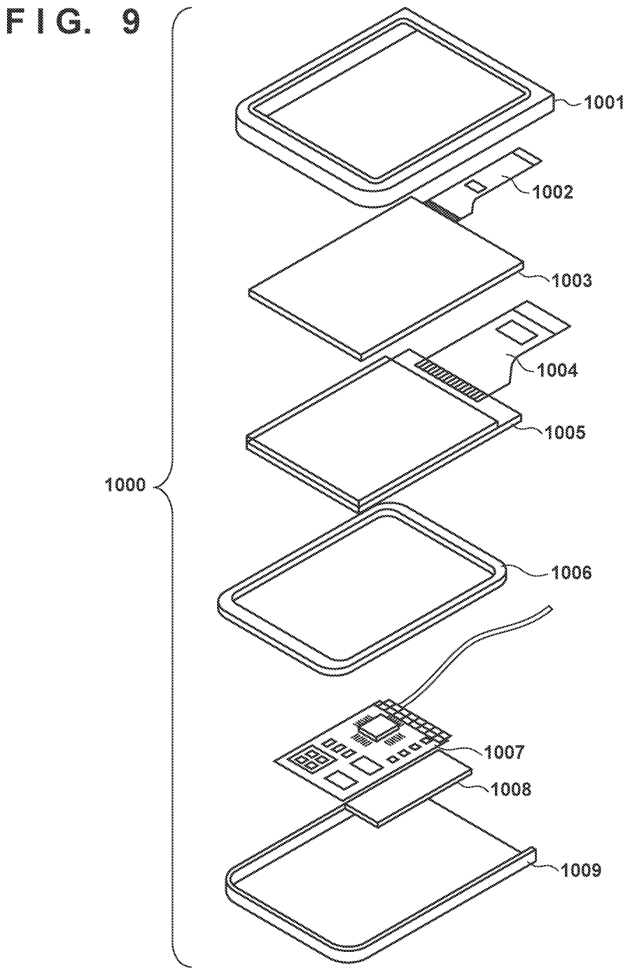

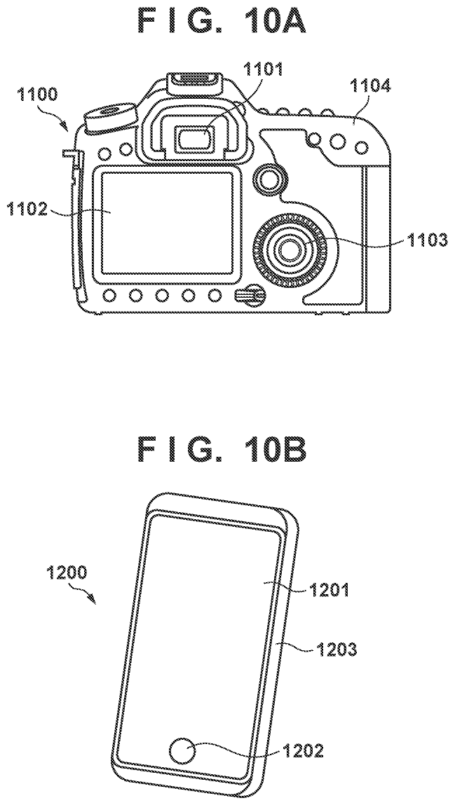

FIG. 10A is a schematic view showing an example of the image capturing device according to the embodiment. An image capturing device 1100 can include a viewfinder 1101, a rear display 1102, an operation unit 1103, and a housing 1104. The viewfinder 1101 may include the display device according to the embodiment. In this case, the display device can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. Therefore, the display device using the organic light emitting element of the present invention is preferably used. This is so because the organic light emitting element has a high response speed. The display device using the organic light emitting element can be used for the apparatuses that require a high display speed more preferably than for the liquid crystal display device.

The image capturing device 1100 includes an optical unit (not shown). This optical unit includes a plurality of lenses, and forms an image on an image sensor that is accommodated in the housing 1104. The focal points of the plurality of lenses can be adjusted by adjusting the relative positions. This operation can also automatically be performed. The image capturing device may be called a photoelectric conversion device. Instead of sequentially capturing an image, the photoelectric conversion device can include, as an image capturing method, a method of detecting the difference from a previous image, a method of extracting an image from an always recorded image, or the like.

FIG. 10B is a schematic view showing an example of an electronic apparatus according to this embodiment. An electronic apparatus 1200 includes a display unit 1201, an operation unit 1202, and a housing 1203. The housing 1203 can accommodate a circuit, a printed board including this circuit, a battery, and a communication unit. The operation unit 1202 may be a button or a touch-panel-type reaction unit. The operation unit may also be a biometric authentication unit that performs unlocking or the like by authenticating a fingerprint. The electronic apparatus including the communication unit can also be regarded as a communication apparatus. The electronic apparatus can further have a camera function by including a lens and an image sensor. An image captured by the camera function is displayed on the display unit. Examples of the electronic apparatus are a smartphone and a laptop computer.

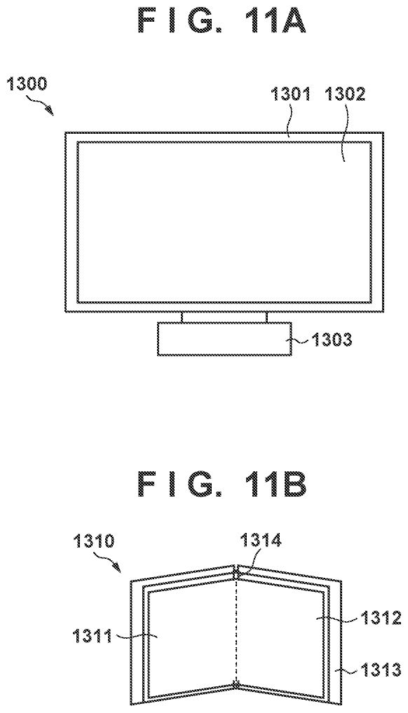

FIG. 11A is a schematic view showing one example of the application examples of the light emitting device according to the embodiment. FIG. 11A shows a display device such as a television monitor or a PC monitor. A display device 1300 includes a frame 1301 and a display unit 1302. The light emitting device according to the embodiment may be used in the display unit 1302. The display device 1300 includes a base 1303 that supports the frame 1301 and the display unit 1302. The base 1303 is not limited to the form shown in FIG. 11A. The lower side of the frame 1301 may also function as the base. In addition, the frame 1301 and the display unit 1302 may be bent. The radius of curvature can be 5,000 mm (inclusive) to 6,000 mm (inclusive).

FIG. 11B is a schematic view showing another example of the application examples of the light emitting device according to the embodiment. A display device 1310 shown in FIG. 11B is configured to be foldable, that is, the display device 1310 is a so-called foldable display device. The display device 1310 includes a first display unit 1311, a second display unit 1312, a housing 1313, and a bending point 1314. Each of the first display unit 1311 and the second display unit 1312 may include the light emitting device according to the embodiment. The first display unit 1311 and the second display unit 1312 may be one seamless display device. The first display unit 1311 and the second display unit 1312 can be divided by the bending point. The first display unit 1311 and the second display unit 1312 can display different images, and can also display one image together.

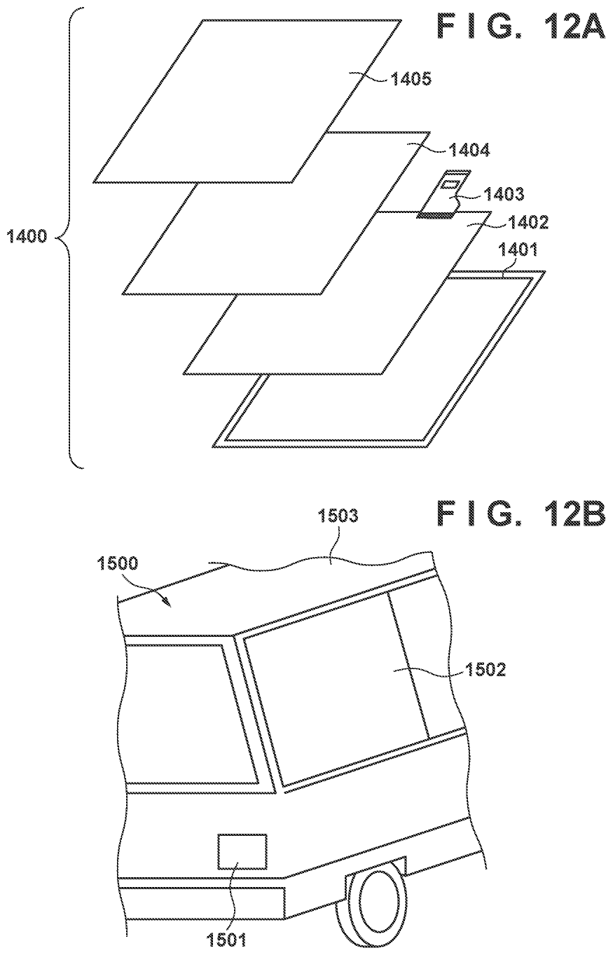

FIG. 12A is a schematic view showing an example of the illumination device according to this embodiment. An illumination device 1400 can include a housing 1401, a light source 1402, a circuit board 1403, an optical film 1404, and a light-diffusing unit 1405. The light source may include the light emitting device according to the embodiment. The optical film can be a filter that improves the color rendering of the light source. When performing lighting-up or the like, the light-diffusing unit can throw the light of the light source over a broad range by effectively diffusing the light. The optical film and the light-diffusing unit can be provided on the illumination light emission side. The illumination device can also include a cover on the outermost portion, as needed.

The illumination device is, for example, a device for illuminating the interior of the room. The illumination device may emit white light, natural white light, or light of any color from blue to red. The illumination device can also include a light control circuit for controlling these light components. The illumination device can also include the organic light emitting element according to the present invention and a power supply circuit connected to the organic light emitting element. The power supply circuit is a circuit for converting an AC voltage into a DC voltage. White has a color temperature of 4,200 K, and natural white has a color temperature of 5,000 K. The illumination device may also include a color filter.

In addition, the illumination device according to this embodiment may include a heat radiation unit. The heat radiation unit radiates the internal heat of the device to the outside of the device, and examples are a metal having a high specific heat and liquid silicon.

FIG. 12B is a schematic view of an automobile as an example of a moving body according to this embodiment. The automobile includes a taillight as an example of the lighting appliance. An automobile 1500 includes a taillight 1501, and can have a form in which the taillight is turned on when performing a braking operation or the like.

The taillight 1501 may include the light emitting device according to the embodiment. The taillight can include a protection member for protecting the organic EL element. The material of the protection member is not limited as long as the material is a transparent material with a strength that is high to some extent, and is preferably polycarbonate. A furandicarboxylic acid derivative, an acrylonitrile derivative, or the like may be mixed in polycarbonate.

The automobile 1500 can include a vehicle body 1503, and a window 1502 attached to the vehicle body 1503. This window may be a window for checking the front and back of the automobile, and can also be a transparent display. This transparent display can include the organic light emitting element according to the embodiment. In this case, the constituent materials of the electrodes and the like of the organic light emitting element are formed by transparent members.

The moving body according to this embodiment can be a ship, an airplane, a drone, or the like. The moving body can include a main body and a lighting appliance provided on the main body. The lighting appliance can emit light for making a notification of the position of the main body. The lighting appliance includes the organic light emitting element according to the embodiment.

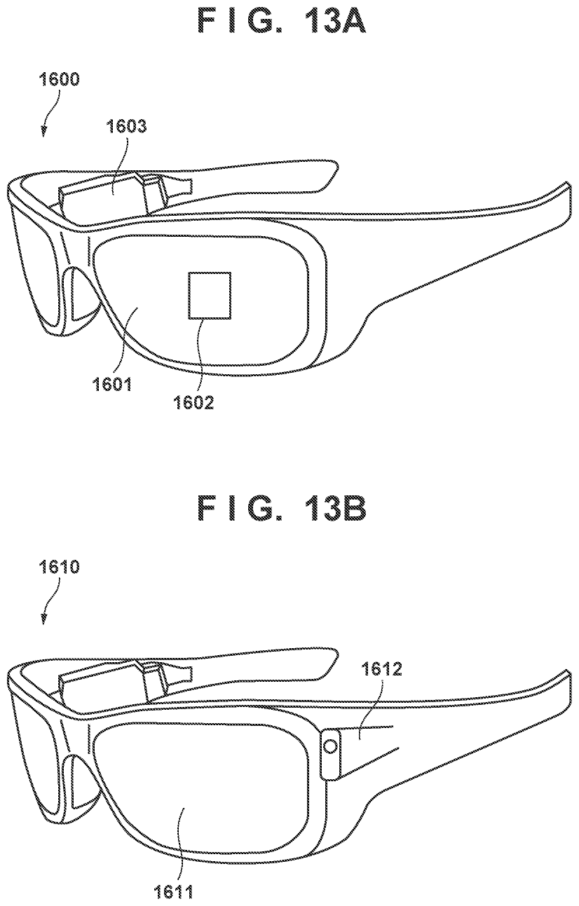

Application examples of the display device according to each embodiment described above will be described with reference to FIGS. 13A and 13B. The display device can be applied to a system that can be worn as a wearable device such as smartglasses, an HMD, or a smart contact lens. An image capturing display device used in such an application example includes an image capturing device capable of photoelectrically converting visible light and a display device capable of emitting visible light.

Glasses 1600 (smartglasses) according to one application example will be described with reference to FIG. 13A. An image capturing device 1602 such as a CMOS sensor or an SPAD is provided on the front surface side of a lens 1601 of the glasses 1600. In addition, the display device of each of the above-described embodiments is provided on the back surface side of the lens 1601.

The glasses 1600 further include a control device 1603. The control device 1603 functions as a power supply that supplies power to the image capturing device 1602 and the display device according to each embodiment. In addition, the control device 1603 controls the operations of the image capturing device 1602 and the display device. An optical system configured to condense light to the image capturing device 1602 is formed on the lens 1601.

Glasses 1610 (smartglasses) according to one application example will be described with reference to FIG. 13B. The glasses 1610 includes a control device 1612, and an image capturing device corresponding to the image capturing device 1602 and a display device are mounted on the control device 1612. The image capturing device in the control device 1612 and an optical system configured to project light emitted from the display device are formed in a lens 1611, and an image is projected to the lens 1611. The control device 1612 functions as a power supply that supplies power to the image capturing device and the display device, and controls the operations of the image capturing device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to the embodiment of the present invention may include an image capturing device including a light receiving element, and a displayed image on the display device may be controlled based on the line-of-sight information of the user from the image capturing device.

More specifically, the display device decides a first visual field region at which the user is gazing and a second visual field region other than the first visual field region based on the line-of-sight information. The first visual field region and the second visual field region may be decided by the control device of the display device, or those decided by an external control device may be received. In the display region of the display device, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

When performing display control based on line-of-sight detection, smartglasses further including an image capturing device configured to capture the outside can preferably be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-087102, filed May 27, 2022, which is hereby incorporated by reference herein in its entirety.

What is claimed is:

1. A light emitting device in which a light emitting element layer including a plurality of light emitting elements, a first substrate including at least a part of each of a plurality of unit circuits respectively connected to the plurality of light emitting elements, and a second substrate including at least a part of a control circuit configured to control the plurality of unit circuits are stacked, the device comprising
a first protective circuit arranged in the first substrate, and configured to protect the plurality of unit circuits,
wherein a maximum voltage in the first substrate is higher than a maximum voltage in the second substrate.

2. The device according to claim 1, further comprising
a first pad electrode electrically connected to the first protective circuit.

3. The device according to claim 2, wherein
the first substrate is arranged between the light emitting element layer and the second substrate, and
the first pad electrode is arranged in the second substrate.

4. The device according to claim 3, wherein
a first opening portion configured to expose the first pad electrode is provided in the second substrate.

5. The device according to claim 4, wherein
the first substrate includes a first semiconductor substrate and a first wiring layer stacked on the first semiconductor substrate,
the first semiconductor substrate is arranged between the light emitting element layer and the first wiring layer,
each of the plurality of light emitting elements and a corresponding unit circuit among the plurality of unit circuits are electrically connected to each other via a penetrating electrode provided in the first semiconductor substrate, and
the first wiring layer includes a conductive path configured to electrically connect the first protective circuit and the first pad electrode.

6. The device according to claim 5, wherein
the second substrate includes a second semiconductor substrate and a second wiring layer stacked on the second semiconductor substrate, and
the second wiring layer is arranged between the first substrate and the first semiconductor substrate.

7. The device according to claim 4, wherein
the first substrate includes a first semiconductor substrate and a first wiring layer stacked on the first semiconductor substrate, and
the first wiring layer is arranged between the light emitting element layer and the first semiconductor substrate.

8. The device according to claim 1, further comprising
a second protective circuit configured to protect the control circuit.

9. The device according to claim 8, wherein
the second protective circuit is arranged in the first substrate.

10. The device according to claim 9, further comprising
a second pad electrode electrically connected to the second protective circuit,
wherein a second opening portion configured to expose the second pad electrode is provided in the second substrate.

11. The device according to claim 4, further comprising:
a second protective circuit arranged in the first substrate, and configured to protect the control circuit; and
a second pad electrode electrically connected to the second protective circuit,
wherein a second opening portion configured to expose the second pad electrode is provided in the second substrate.

12. The device according to claim 8, wherein
the second protective circuit is arranged in the second substrate.

13. The device according to claim 12, further comprising:
a first pad electrode arranged in the second substrate, and electrically connected to the first protective circuit; and
a second pad electrode arranged in the second substrate, and electrically connected to the second protective circuit,
wherein a first opening portion configured to expose the first pad electrode and a second opening portion configured to expose the second pad electrode are provided in the second substrate.

14. The device according to claim 2, wherein
the first substrate is arranged between the light emitting element layer and the second substrate,
the first pad electrode is arranged in the first substrate, and
a first opening portion configured to expose the first pad electrode is provided in the first substrate.

15. The device according to claim 14, further comprising:
a second protective circuit arranged in the second substrate, and configured to protect the control circuit; and
a second pad electrode arranged in the first substrate, and electrically connected to the second protective circuit.

16. The device according to claim 12, further comprising:
a first pad electrode arranged in the first substrate, and electrically connected to the first protective circuit; and
a second pad electrode arranged in the first substrate, and electrically connected to the second protective circuit,
wherein a first opening portion configured to expose the first pad electrode and a second opening portion configured to expose the second pad electrode are provided in the first substrate.

17. The device according to claim 1, wherein
the light emitting element layer includes an organic light emitting element.

18. An image capturing device comprising an optical unit including a plurality of lenses, an image sensor configured to receive light having passed through the optical unit, and a light emitting device defined in claim 1 configured to display an image captured by the image sensor.

19. An electronic apparatus comprising a light emitting device defined in claim 1, a housing provided with the light emitting device, and a communication unit provided in the housing and configured to perform external communication.

20. A moving body comprising a light emitting device defined in claim 1.
